(19) United States
(12) Patent Application Publication
(10) Pub. No.: US 2026/0280527 A1
(43) Pub. Date: Sep. 17, 2026

(54) COMMUNICATION DEVICE AND METHOD FOR ADAPTIVE SAW FILTER BYPASS

(71) Applicant: MEDIATEK INC., Hsinchu City (TW)

(72) Inventors: Chu-Jung Hsu, Hsinchu City (TW); Shi-Wen Liu, Hsinchu City (TW); Sin-Han Yang, Hsinchu City (TW); Yu-Tsung Lo, Hsinchu City (TW); Chi-Sheng Yu, Hsinchu City (TW); Hua-Shan Chou, Hsinchu City (TW); Chao-Wei Wang, Hsinchu City (TW); Shih-Hsi Hu, Hsinchu City (TW)

(73) Assignee: MEDIATEK INC., Hsinchu City (TW)

(21) Appl. No.: 19/562,786

(22) Filed: Mar. 11, 2026

Related U.S. Application Data
(60) Provisional application No. 63/769,824, filed on Mar. 11, 2025.

(51) Int. Cl. H03H 9/64; H04B 17/318

(52) U.S. Cl. CPC H03H 9/6489; H04B 17/328

(57) ABSTRACT

A method for adaptively selecting a signal path in a communication device is disclosed. The communication device includes a first path including a surface acoustic wave (SAW) filter and a second path that does not include a SAW filter for receiving a signal. The method includes detecting a power level of a reference signal derived from a received signal, wherein the received signal is received through one of the first path and the second path; detecting an interference power of the received signal; detecting a quality of the received signal; selecting a path from the first path and the second path based on at least one of the power level of the reference signal, the interference power of the received signal, and the quality of the received signal; and using the selected path to receive a subsequent signal.

### CROSS REFERENCE TO RELATED APPLICATIONS

This application claims the benefit of U.S. Provisional Application No. 63/769,824, filed on March 11th, 2025. The content of the application is incorporated herein by reference.

### BACKGROUND

In modern wireless communication systems, such as 5G communication systems, enhancing receiver (RX) performance, particularly in weak signal conditions, is a primary objective. The receiver sensitivity is a critical performance metric, and minimizing signal loss in the front-end circuitry is essential for maximizing this sensitivity.

As wireless communication technologies have evolved from 2G systems to 3G, 4G, and now 5G systems, the complexity of the front-end architecture has increased substantially. To accommodate a greater number of frequency bands and advanced features, more components such as switches and filters, are integrated into the front-end modules. While these components provide enhanced functionality, they also introduce additional signal loss into the receiver path. The cumulative effect is that as the communication system evolves, the front-end loss tends to increase, which can degrade overall receiver performance.

Conventional front-end designs typically include filters, for example, surface acoustic wave (SAW) filters, to protect the receiver from unwanted signals and interference. The receiver signal path is routed through these SAW filters to ensure that any potential interference is suppressed. However, this conventional approach has a limitation. The signal is forced to pass through the path containing the SAW filter irrespective of the current operating environment. In scenarios where no significant interference is present, routing the signal through the filter introduces unnecessary signal loss. This inherent loss degrades receiver sensitivity, an effect that is particularly detrimental in weak signal areas where maximizing signal integrity is critical.

Therefore, a need exists for an improved method and device that can adaptively configure the receiver path to optimize performance based on the current environmental conditions.

### SUMMARY

In an embodiment, a method for adaptively selecting a signal path in a communication device is provided. The communication device comprises a first path and a second path for receiving a signal, wherein the first path comprises a surface acoustic wave (SAW) filter, and the second path does not comprise a SAW filter. The method comprises detecting a power level of a reference signal derived from a received signal, wherein the received signal is received through one of the first path and the second path, detecting an interference power of the received signal, detecting a quality of the received signal, selecting a path from the first path and the second path based on at least one of the power level of the reference signal, the interference power of the received signal, and the quality of the received signal, and using the selected path to receive a subsequent signal.

In another embodiment, a communication device is also provided. The communication device comprises an integrated module comprising a first path and a second path, wherein the first path comprises a surface acoustic wave (SAW) filter and a first low noise amplifier (LNA) coupled to the SAW filter, and the second path comprises a second LNA and does not comprise a SAW filter; a radio frequency integrated circuit (RFIC) coupled to the integrated module and configured to detect an interference power of a received signal, wherein the received signal is received through one of the first path and the second path; and a baseband integrated circuit (IC) coupled to the RFIC and configured to select a path from the first path and the second path based on at least one of a power level of a reference signal derived from the received signal, the interference power of the received signal, and a quality of the received signal.

In an embodiment, the first LNA in the first path and the second LNA in the second path share a single LNA. In an embodiment, each of the first LNA and the second LNA uses respective LNA.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic block diagram of a communication device according to an embodiment of the present invention.

FIG. 2 is a schematic block diagram illustrating an embodiment of an internal bypass path within an integrated module of the communication device.

FIG. 3 is a schematic block diagram illustrating an embodiment of an external bypass path for the integrated module of the communication device.

FIG. 4 is a conceptual diagram comparing a conventional signal path comprising a filter with a bypass signal path according to an embodiment of the present invention.

FIG. 5 is a schematic block diagram of a receiver chain illustrating an interference detection mechanism according to an embodiment of the present invention.

FIG. 6 is a timing diagram illustrating the timing for performing interference detection according to an embodiment of the present invention.

FIG. 7 is a flowchart illustrating a procedure for entering a bypass mode of operation according to an embodiment of the present invention.

FIG. 8 is a flowchart illustrating a procedure for exiting the bypass mode of operation according to an embodiment of the present invention.

FIG. 9 is a state diagram illustrating the operating modes of the communication device under different signal and interference conditions according to an embodiment of the present invention.

FIG. 10 is a schematic block diagram illustrating signal paths in a standard operating mode where both transmitter (TX) and receiver (RX) paths operate without bypass.

FIG. 11 is a schematic block diagram illustrating signal paths in an operating mode where both the TX path and the RX path operate with bypass.

FIG. 12 is a schematic block diagram illustrating signal paths in a mixed operating mode where the TX path operates with bypass and the RX path operates without bypass.

FIG. 13 is a schematic block diagram illustrating signal paths in a mixed operating mode where the TX path operates without bypass and the RX path operates with bypass.

FIG. 14 is a schematic block diagram of an enhanced embodiment of the communication device, further comprising an additional external low noise amplifier.

FIG. 15 is a schematic block diagram of another embodiment of the communication device, illustrating an optimized bypass path configuration.

### DETAILED DESCRIPTION

The present invention provides a communication device and a method for adaptively selecting a signal path, designed to overcome limitations of conventional front-end architectures. Conventional designs route a received signal through a fixed path that includes a surface acoustic wave (SAW) filter to mitigate potential interference. While effective in noisy environments, this approach imposes an inherent and unnecessary signal loss penalty in conditions where interference is absent. This fixed loss degrades receiver sensitivity, particularly in weak signal areas where maximizing signal integrity is suitable for maintaining reliable communication.

The embodiments of the present invention address this problem by introducing a dynamic bypass mechanism. The communication device is configured to continuously monitor the real-time operating environment by detecting a plurality of parameters, including at least one of a power level of a reference signal derived from a received signal, an interference power of the received signal, and a quality of the received signal. Based on one or more detected parameters, a baseband integrated circuit makes a determination and selects an optimal signal path. The device can select either a first, standard path through the SAW filter for robust interference rejection or a second, low-loss bypass path to improve receiver sensitivity. This adaptive capability ensures that receiver performance is maximized under all environmental conditions.

The adaptive path selection method is applicable to various operating scenarios, including non-carrier aggregation (non-CA) and carrier aggregation (CA) scenarios. In a CA scenario, the communication device can simultaneously transmit a signal on a first frequency band while receiving a signal on a second, different frequency band. In such cases, the transmitted signal from the device's own transmitter can be a source of interference to its receiver. The blocking detector of the present invention is configured to also detect this self-generated interference. Therefore, the baseband integrated circuit can select the appropriate signal path, engaging the SAW filter when self-generated interference is significant, and selecting the bypass path when it is not, thereby optimizing performance even in complex CA operations. This selection of the low-loss bypass path can result in a sensitivity improvement of approximately 1 to 2 dB, depending on the front-end architecture.

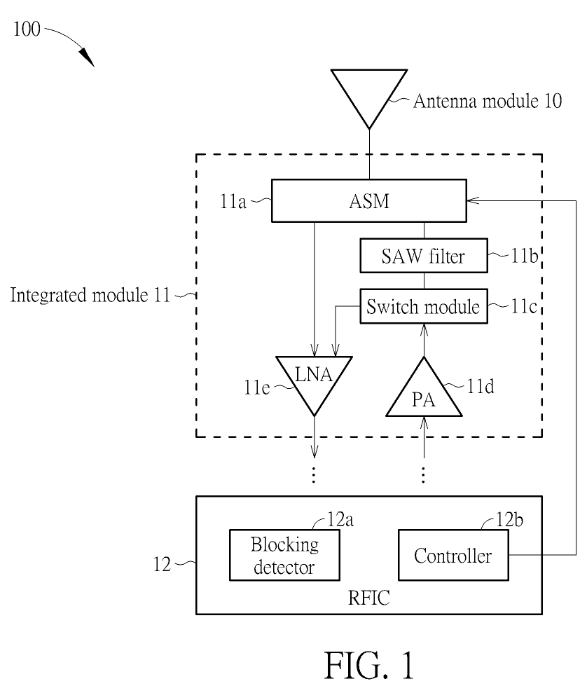

FIG. 1 is a schematic block diagram of a communication device 100 according to an embodiment of the present invention. The communication device 100 is designed to adaptively select a signal path to optimize receiver performance. The communication device 100 includes an antenna module 10, an integrated module 11, and a radio frequency integrated circuit (RFIC) 12.

The antenna module 10 is configured to receive and transmit wireless signals. The integrated module 11 is coupled to the antenna module 10 and serves as a front-end module for processing received signals. The integrated module 11 includes an antenna switch module (ASM) 11a, a surface acoustic wave (SAW) filter 11b, a switch module 11c, a power amplifier (PA) 11d, and a low noise amplifier (LNA) 11e. The ASM 11a can be implemented using a plurality of switches, such as transistor-based switches, and is configured to route signals between the antenna module 10 and internal paths of the integrated module 11. The SAW filter 11b is a filter configured to pass signals within a specific frequency band while rejecting out-of-band signals and interference. The switch module 11c provides additional signal routing capabilities within the integrated module 11, selectively routes an output of the PA 11d to the SAW filter 11b and selectively routes an output of the SAW filter 11b to the LNA 11e. The PA 11d is configured to amplify signals for transmission. The LNA 11e is configured to amplify received signals.

The RFIC 12 is coupled to the integrated module 11 and includes a blocking detector 12a and a controller 12b. The blocking detector 12a is coupled to an input of the RFIC 12 or embedded within the RFIC 12, and is configured to detect an interference power of a received signal to generate a detected power value. In one embodiment, the blocking detector 12a is an Out-of-Band Blocking (OBB) detector. The controller 12bis configured to control the ASM 11a.

In operation, the communication device 100 supports at least two paths for a received signal. A first path is a standard path wherein the received signal from the antenna module 10 is routed by the ASM 11a through the SAW filter 11b and the switch module 11c to the LNA 11e. A second path is a bypass path wherein the received signal is routed by the ASM 11a directly to the LNA 11e, bypassing the SAW filter 11b.

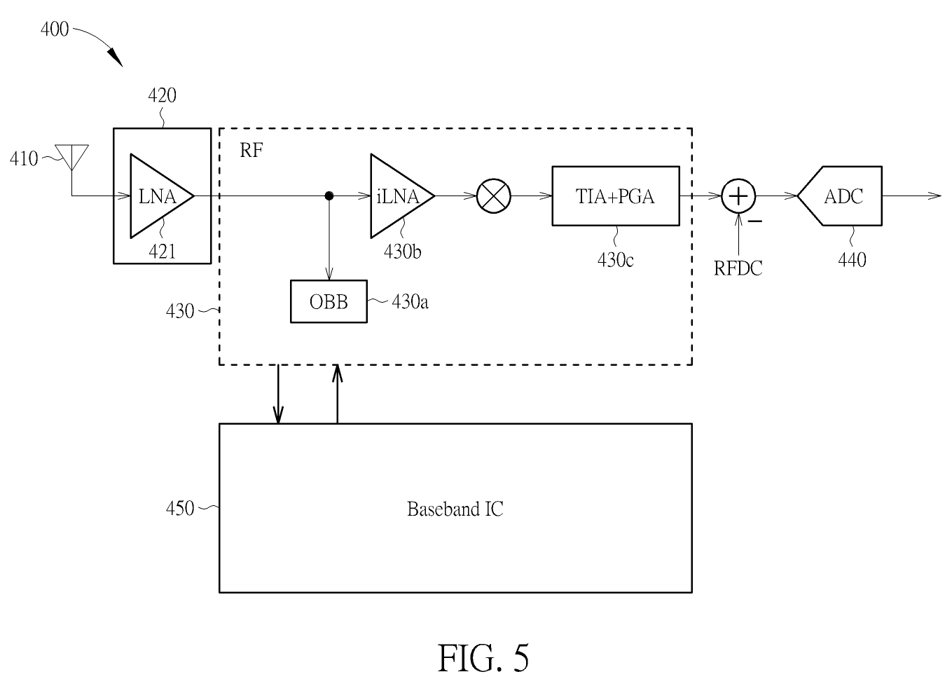

The selection between the first path and the second path is performed adaptively. The RFIC 12 is configured to detect parameters of the received signal, including the interference power detected by the blocking detector 12a, a power level of a reference signal derived from the received signal, and a quality of the received signal. A baseband integrated circuit (shown in FIG. 5), coupled to the RFIC 12, is configured to select one of the first path and the second path based on at least one of these detected parameters. The baseband integrated circuit generates a control signal based on the selection, and the controller 12b within the RFIC 12 controls the ASM 11a according to the control signal to route the received signal through the selected path.

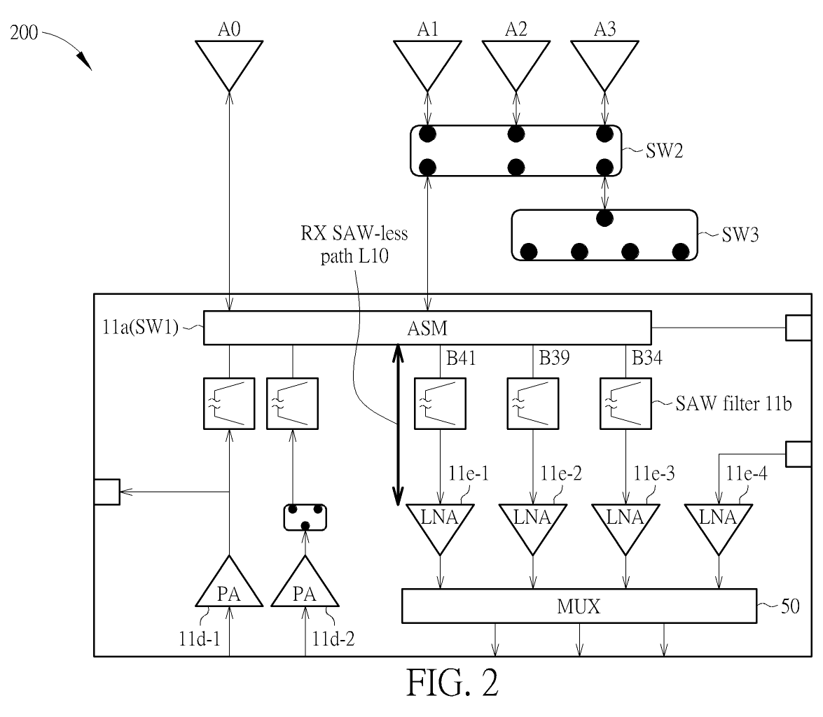

FIG. 2 is a schematic block diagram of a communication device 200 illustrating an embodiment of an internal bypass path within an integrated module. The communication device 200 includes a plurality of antennas A0-A3, which correspond to the antenna module 10 shown in FIG. 1. The communication device 200 further includes a second switch SW2, a third switch SW3, and an integrated module similar to the one described in FIG. 1. The second switch SW2 and the third switch SW3 are external switches. The integrated module is a multi-band front-end module configured to process signals for a plurality of frequency bands, such as B41, B39, and B34.

Furthermore, the principles of the present invention are applicable across a wide spectrum of operating frequencies. The adaptive bypass architecture can be implemented for various communication bands, including, but not limited to, Low-Band (L-Band), Mid-Band (M-Band), High-Band (H-Band), and other custom frequency bands (CB).

The integrated module includes an ASM 11a, a plurality of SAW filters 11b, a plurality of PAs 11d-1 and 11d-2, a plurality of LNAs 11e-1, 11e-2, 11e-3, and 11e-4, and a multiplexer (MUX) 50. In this embodiment, the ASM 11a can be regarded as a first switch (SW1) and is configured to route signals to different paths corresponding to the different frequency bands. Each frequency band is associated with a respective SAW filter 11b and LNA. For example, the frequency band B41 is associated with an SAW filter 11b and the LNA 11e-1. The MUX 50 is coupled to outputs of the plurality of LNAs. For example, the MUX 50 has M input terminals and N output terminals. The M input terminals are coupled to corresponding LNAs. The MUX 50 is used to transfer the signal from outputs of the plurality of LNAs to the output terminals.

This embodiment illustrates an internal implementation of the first path and the second path. For the frequency band B41, a first path includes a SAW filter 11b and a LNA 11e-1 and is a standard path wherein a received signal is routed from the ASM 11a through the corresponding SAW filter 11b and the LNA 11e-1 to the MUX.

The feature of this embodiment is an internal bypass path, designated as RX SAW-less path L10. The ASM 11a is further configured to selectively route the received signal to a second path, which is the RX SAW-less path L10. The RX SAW-less path L10 is disposed entirely within the integrated module and comprises a trace and the LNA 11e-1. The trace in the RX SAW-less path L10 routes the signal from an output of the ASM 11a directly to the input of the LNA 11e-1, thereby bypassing the SAW filter 11b associated with the frequency band B41. The selection of either the first path or the RX SAW-less path L10 is controlled by the ASM 11a based on a control signal from a baseband integrated circuit, as previously described. This internal bypass architecture provides an advantage, such as minimizing signal loss. This internal bypass architecture provides a compact solution for adaptively reducing receiver path loss.

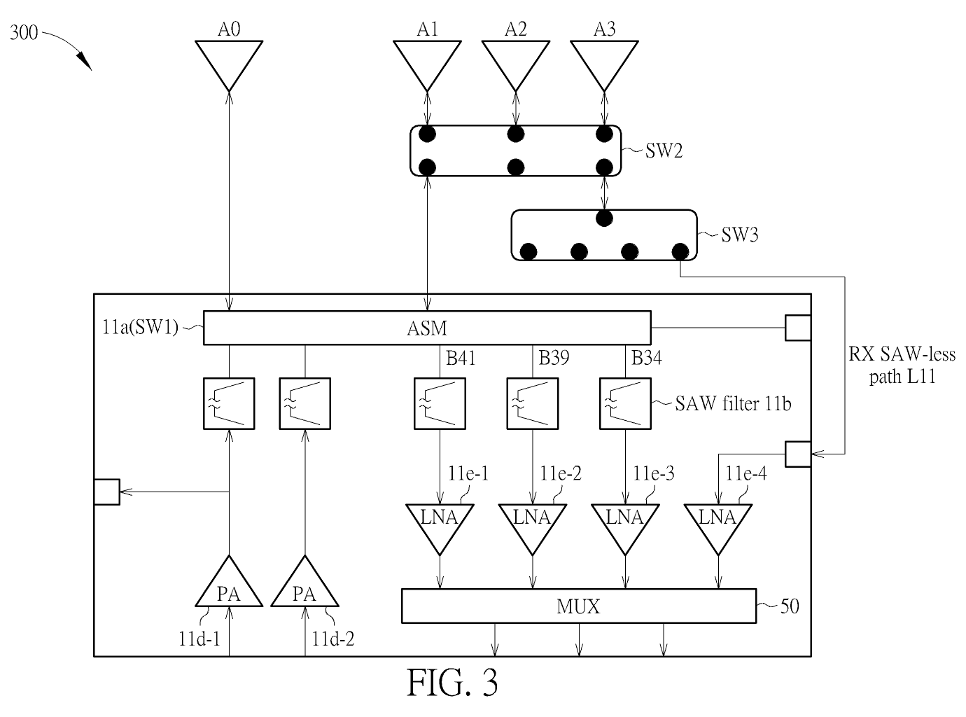

FIG. 3 is a schematic block diagram of a communication device 300 illustrating an embodiment of an external bypass path for an integrated module. The communication device 300 includes a plurality of antennas A0-A3, a second switch SW2, a third switch SW3, and an integrated module. The integrated module includes an ASM 11a functioning as a first switch (SW1), a plurality of SAW filters 11b, a plurality of PAs, a plurality of LNAs 11e-1, 11e-2, 11e-3, and 11e-4, and a multiplexer (MUX) 50. The second switch SW2 and the third switch SW3 are external switches.

A first path, designated as an SAW path, is disposed within the integrated module, wherein the SAW path comprises a SAW filter 11b and a corresponding LNA. For example, a received signal from antenna A1 is routed through the ASM 11a, a corresponding SAW filter 11b and the LNA 11e-1 to the MUX.

The feature of this embodiment is a second path, designated as RX SAW-less path L11. The RX SAW-less path L11 comprises a trace disposed externally to the integrated module and the LNA 11e-4. The trace is configured to route a received signal from the antennas A1-A3, through the second switch SW2 and the third switch SW3, to a port of the integrated module. The signal is then routed directly to an input of the LNA 11e-4. This external routing bypasses both the ASM 11a and the SAW filter 11b. The selection of either the first path or the RX SAW-less path L11 is controlled by the second switch SW2 and the third switch SW3 based on a control signal from a baseband integrated circuit. This external bypass architecture provides a flexible alternative for implementing the adaptive signal path selection. A signal at a band from the LNA 11e-1 in the first path and a signal at the same band from the LNA 11e-4 in the second path are routed to the same output terminal of the MUX.

In this embodiment, the second switch SW2 and the third switch SW3 can be controlled to route signals of different bands from the antennas A1-A3 to the port of the integrated module at different times. The signals of the different bands can share the RX SAW-less path L11.

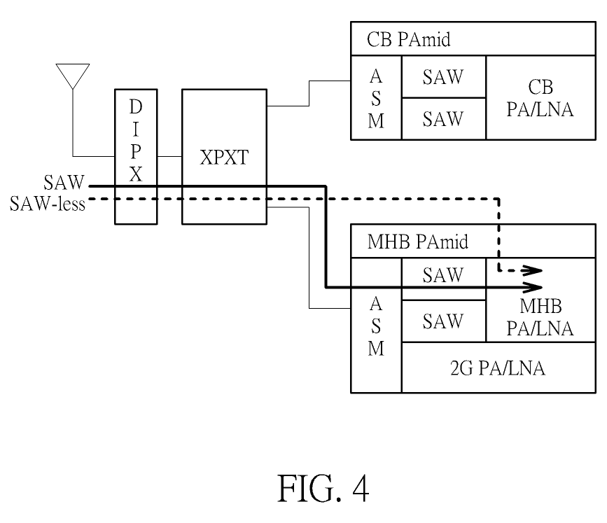

FIG. 4 is a conceptual diagram comparing a conventional signal path (designated as an SAW path) with a bypass signal path (designated as an SAW-less path) according to an embodiment of the present invention. The diagram illustrates a portion of a modern front-end architecture, which can include a diplexer (DIPX), a switch (XPXT), and a plurality of integrated modules (PAmids), such as a mid-band and high-band PAmid (MHB PAmid) and a 3.5GHz frequency band PAmid (CB PAmid).

The SAW path represents a conventional or default receiver path. In this path, a received signal is routed through the DIPX and the XPXT to an input of the MHB PAmid. Within the MHB PAmid, the signal passes through an ASM and then through a filtering component, such as a SAW filter, before reaching an LNA. The inclusion of the SAW filter in the signal path introduces a known amount of signal loss, which can degrade receiver sensitivity.

The SAW-less path represents the bypass path provided by the present invention. In this path, the XPXT is controlled to route the received signal to an alternative input of the MHB PAmid. This alternative input is coupled directly to the LNA, thereby completely bypassing the internal ASM and the SAW filter. By avoiding the signal loss associated with the filtering components, the SAW-less path provides an improvement in receiver sensitivity. The diagram illustrates the principle of the invention, which is to dynamically select the SAW-less path in low-interference environments to enhance performance, and to revert to the SAW path when interference filtering is required.

FIG. 5 is a schematic block diagram of a receiver chain 400 illustrating an interference detection mechanism according to an embodiment of the present invention. The receiver chain 400 details the components involved in detecting interference power, which is a parameter for the adaptive path selection logic. The receiver chain 400 includes an antenna 410, an integrated module 420, a radio frequency integrated circuit (RFIC) 430, an analog-to-digital converter (ADC) 440, and a baseband integrated circuit (IC) 450.

The antenna 410 receives a wireless signal, which is then amplified by an LNA 421. The LNA 421 can be a component within the integrated module 420, such as the integrated module 11 (i.e., front-end) shown in FIG. 1. The amplified signal from the LNA 421 is provided to an input of the RFIC 430.

The RFIC 430 is configured to process the received signal from the integrated module 420. Within the RFIC 430, the signal path includes an internal LNA (iLNA) 430b, a mixer, and a transimpedance amplifier with a programmable gain amplifier (TIA+PGA) 430c. The processed analog signal is then converted into a digital signal by the ADC 440.

A feature of this embodiment is the interference detection mechanism implemented within the RFIC 430. The RFIC 430 includes an Out-of-Band Blocking (OBB) detector 430a, which serves as a specific embodiment of the blocking detector 12a shown in FIG. 1. The OBB detector 430a is coupled to the input of the RFIC 430, before the iLNA 430b, and is configured to measure the power of out-of-band interference signals. The interference signals measured by the OBB detector 430a can include various types of interference, for instance, continuous wave (CW) interference and/or modulated signal interference.

The operation is controlled by the baseband IC 450, which is coupled to the RFIC 430. The baseband IC 450 initiates the detection process by sending a control command to the RFIC 430. In response, the RFIC 430 utilizes the OBB detector 430a to measure the interference power and reports the detected interference power value back to the baseband IC 450. The baseband IC 450 then uses this detected interference power value, along with other parameters such as the power level of a reference signal derived from the received signal and the quality of the received signal, to make the final determination of whether to select the first path (SAW path) or the second path (SAW-less path). The reference signal derived from the received signal can be a signal output from the ADC 440.

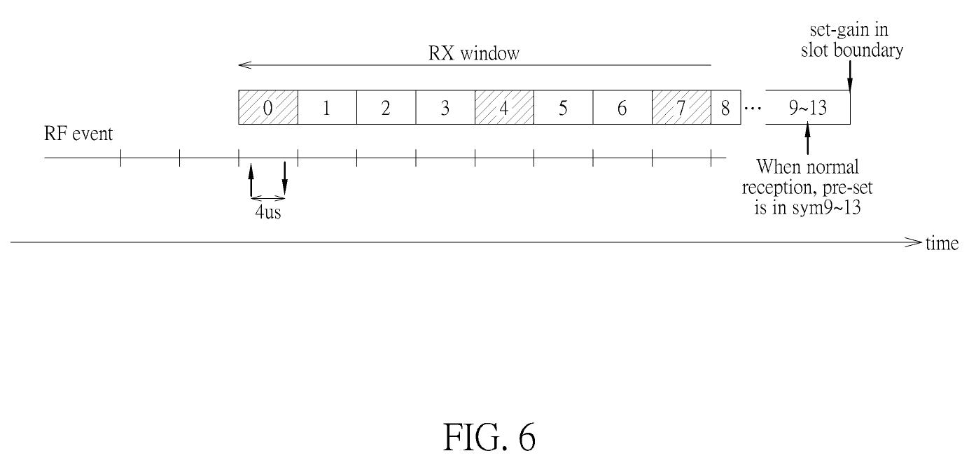

FIG. 6 is a timing diagram illustrating the scheduling of the interference detection process according to an embodiment of the present invention. The diagram shows a timeline of radio frequency (RF) events within a single slot of a received signal. In an embodiment, a slot comprises a plurality of symbols, for example, fourteen symbols numbered from 0 to 13.

The detection of interference power, performed by the OBB detector 430a, is strategically scheduled to occur during an initial symbol of the slot, designated as Symbol 0. To achieve a robust and accurate measurement, the detection can be performed a plurality of times within the duration of this initial symbol. For example, Symbol 0 can have a duration of 33 microseconds, within which the detection is performed six times (i.e., the detection is performed every 4 microseconds, so it needs 24 microseconds). Multiple interference power values obtained by multiple detections can be averaged. The averaged interference power value is used when the baseband IC selects the path.

The timing diagram further illustrates a slot-level control mechanism. The interference power is detected during a first slot (e.g., slot N-1), and this information is used by the baseband IC 450 to make a determination. The resulting selection of either the first path or the second path is then applied for a subsequent, second slot (e.g., slot N) so that the subsequent, second slot (e.g., slot N) is received by the selected path.

Additionally, FIG. 6 shows other events within the slot, such as a gain pre-setting procedure that occurs in later symbols (e.g., symbols 9-13), with the gain being set at the slot boundary. The detection in Symbol 0 is performed under a stable gain condition to ensure the accuracy of the measurement. This precisely timed detection process enables the communication device to adapt to changing environmental conditions on a slot-by-slot basis.

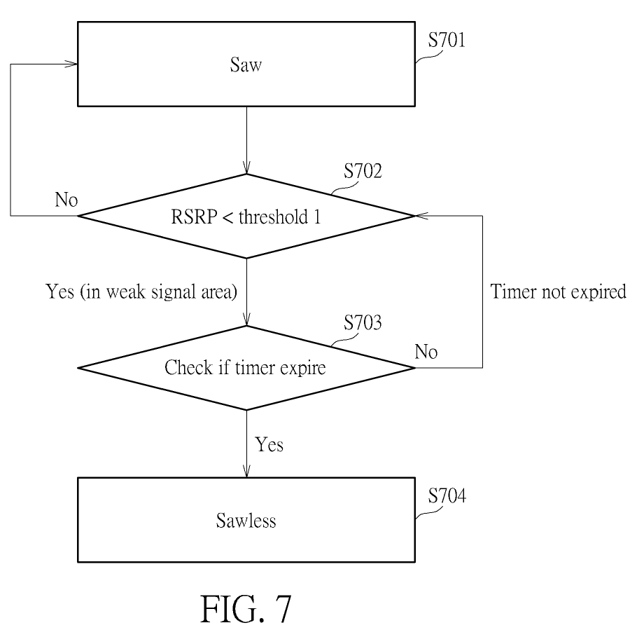

FIG. 7 is a flowchart illustrating a procedure for entering a bypass mode (designated as an SAW-less mode) from a default mode (designated as an SAW mode) according to an embodiment of the present invention. The procedure ensures that the transition to the SAW-less mode occurs only under stable and appropriate conditions.

The procedure begins at step S701, where the communication device operates in the SAW mode as an initial state to receive a signal at a band. In the SAW mode, the first path comprising the SAW filter is selected for signal reception.

At step S702, a determination is made as to whether a power level of a reference signal derived from the received signal, specifically a Reference Signal Received Power (RSRP), is less than a first threshold. This step is performed to determine if the communication device is in a weak signal area. A weak signal area typically corresponds to a physical location where the communication device is far from a serving base station, while a strong signal area corresponds to a location close to the base station. If the RSRP is not less than the first threshold, the device is considered to be in a strong signal area, and the procedure returns to step S701, maintaining the device in the SAW mode. If the RSRP is less than the first threshold, indicating a weak signal area, the procedure proceeds to the next step.

At step S703, a timer is checked to determine if the state in which the power level of a reference signal is less than the first threshold has been maintained for a predetermined period. This step serves as a stability check to prevent rapid switching between modes due to transient fluctuations in signal strength, an effect often referred to as a Ping-Pong effect. It should be understood that each switching event between modes can introduce a brief gap in signal reception, and excessive, rapid switching can lead to a cumulative loss of data throughput. The procedure only proceeds if the condition detected (i.e. the power level of a reference signal is less than the first threshold) in step S702 has persisted for the predetermined period. If the timer has not expired, the procedure returns to step S702 to continue monitoring the RSRP.

For example, the predetermined period can be 1 second. The determination operation is executed every 5 milliseconds. If the result of each determination is that the power level of a reference signal is less than the first threshold, the state that the power level of a reference signal is less than the first threshold is considered to have persisted for 1 second.

If the timer has expired at step S703, indicating that the device has been in a stable weak signal condition for the predetermined period, the procedure proceeds to step S704. At step S704, the communication device transitions to the SAW-less mode by selecting the second, bypass path to receive the signal at the band.

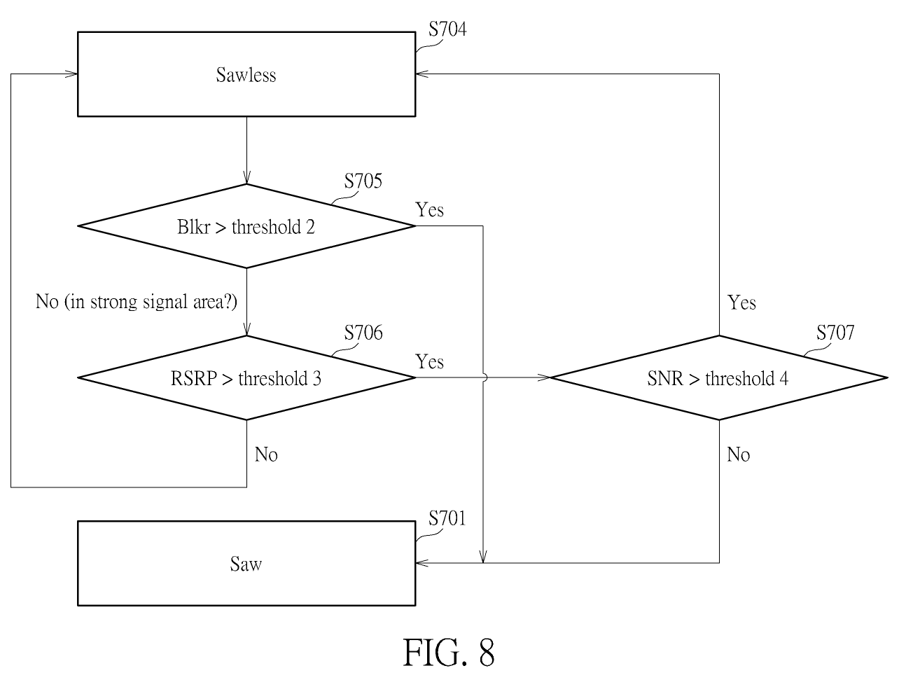

FIG. 8 is a flowchart illustrating a procedure for maintaining or exiting the SAW-less mode based on changing environmental conditions, according to an embodiment of the present invention. The procedure begins at step S704, where the communication device is currently operating in the SAW-less mode to receive the signal at the band.

At step S705, a determination is made as to whether an interference power (Blkr) of a received signal is greater than a second threshold. This step is the primary safety check. If the interference power is greater than the second threshold, it indicates that the operating environment is no longer suitable for a filter-less path. Consequently, the procedure proceeds to step S701, and the communication device transitions back to the SAW mode to re-engage the SAW filter.

If the interference power is not greater than the second threshold at step S705, the procedure continues to step S706. At step S706, a determination is made as to whether the power level of the reference signal (RSRP) is greater than a third threshold. This step checks if the device has moved from a weak signal area to a strong signal area. If the RSRP is not greater than the third threshold, the device remains in a weak signal area with low interference, which is the ideal condition for the SAW-less mode. In this case, the procedure loops back to step S704, maintaining the device in the SAW-less mode.

If the RSRP is found to be greater than the third threshold at step S706, indicating that the device is now in a strong signal area, a further check is performed at step S707. At step S707, a determination is made as to whether a quality of the received signal (i.e., Signal-to-Noise-Ratio, SNR) is greater than a fourth threshold. This step provides operational flexibility in strong signal areas. If the SNR is greater than the fourth threshold, the signal quality is still high, and the device is permitted to maintain the selection of the SAW-less mode by looping back to step S704. However, if the SNR is not greater than the fourth threshold, it indicates that the signal quality has degraded. For stability, the procedure proceeds to step S701, transitioning the device back to the SAW mode to receive the signal at the band.

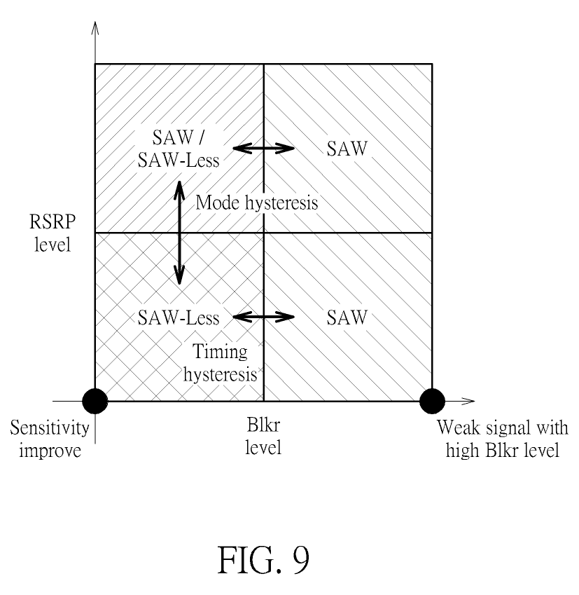

FIG. 9 is a state diagram illustrating the operating modes of the communication device under different signal and interference conditions, according to an embodiment of the present invention. The diagram is defined by two axes: a vertical axis representing the power level of a reference signal (RSRP level), and a horizontal axis representing the interference power (Blkr level). These two axes divide the operational space into four quadrants, each corresponding to a specific operating mode.

In the two right-hand quadrants, where the Blkr level is high, the communication device is always set to the SAW mode. This is a protective measure to ensure that the SAW filter is engaged to reject the high interference, regardless of whether the RSRP level is high or low.

In the lower-left quadrant, representing a condition with a low RSRP level and a low Blkr level (i.e., a weak signal environment with low interference), the communication device operates in the SAW-less mode. This is the optimal condition for the bypass path, as it results in an improvement in receiver sensitivity.

In the upper-left quadrant, representing a condition with a high RSRP level and a low Blkr level (i.e., a strong signal environment with low interference), the operating mode is designated as SAW / SAW-Less. This indicates that the device can operate in either mode, with the final selection depending on a further quality check of the received signal (i.e., the SNR), as detailed in the flowchart of FIG. 8.

FIG. 9 also illustrates two types of hysteresis designed to ensure stable operation and prevent rapid, undesirable switching. A “Timing hysteresis” governs the transition from the lower-right quadrant (SAW mode) to the lower-left quadrant (SAW-less mode). This ensures the device only enters the SAW-less mode after confirming a stable, low-interference condition over a period of time. A “Mode hysteresis” governs the transitions between the lower-left and upper-left quadrants. This ensures that the device can transition from a weak-signal SAW-less state to a strong-signal SAW-less state, but cannot directly enter the SAW-less mode from a strong signal state, thereby enhancing operational stability. Because the data throughput is relatively high under the strong signal state condition, if a mode transition is performed under the strong signal state condition, a gap of mode transition can cause data loss.

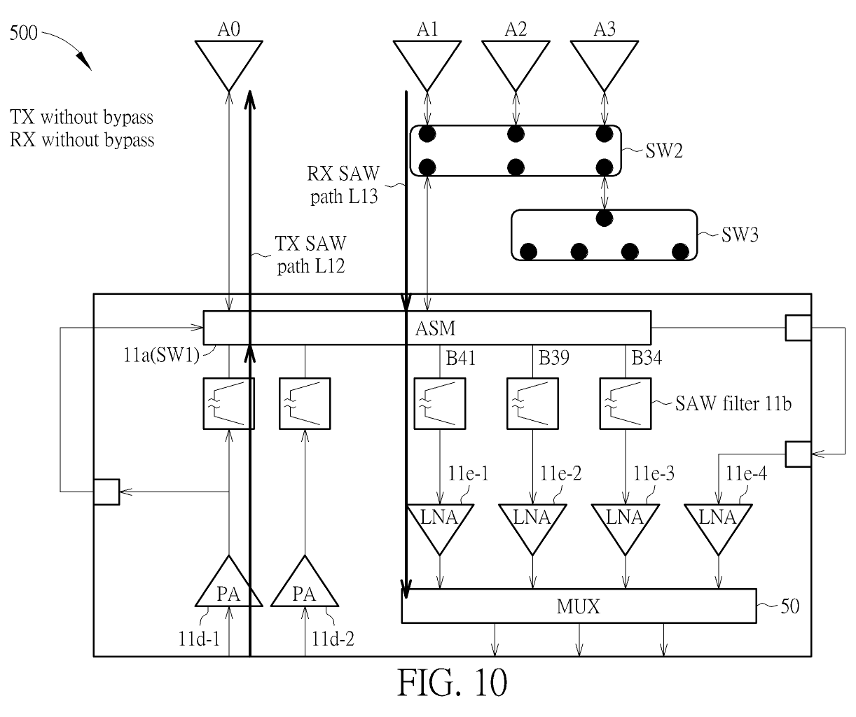

FIG. 10 is a schematic block diagram of a communication device 500 illustrating a standard operating mode where both transmitter (TX) and receiver (RX) signal paths operate without bypass. This configuration serves as a baseline to illustrate the conventional signal routing within the front-end architecture. The communication device 500 includes components similar to those described in previous figures, such as a plurality of antennas A0-A3, a second switch SW2, a third switch SW3, and an integrated module (front-end).

In this standard operating mode, two conventional signal paths are shown: a TX SAW path L12 and an RX SAW path L13. The TX SAW path L12 illustrates a standard transmission sequence. A signal generated by a PA within the integrated module is routed through a corresponding SAW filter 11b and the ASM 11a, and is subsequently transmitted via the antenna A0. This path ensures that the transmitted signal is properly filtered before being radiated.

The RX SAW path L13 illustrates a standard reception sequence. A signal is received by the antenna A1 and is routed into the integrated module through the ASM 11a. The signal then passes through a corresponding SAW filter 11b before being amplified by an LNA (e.g., LNA 11e-1). This path represents the default filtering operation for received signals.

FIG. 10 thus illustrates the operation of the communication device 500 when the adaptive bypass feature is inactive, with both TX and RX signals being routed through their respective SAW filters.

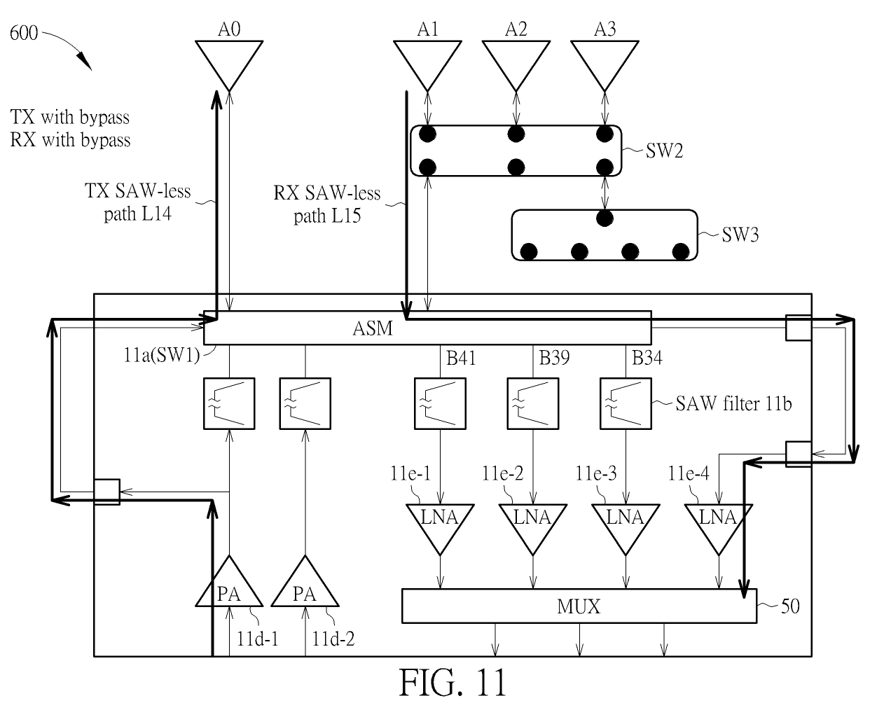

FIG. 11 is a schematic block diagram of a communication device 600 illustrating an operating mode where both the TX path and the RX path operate with bypass. This configuration demonstrates a high-performance mode where signal loss is minimized for both transmission and reception. The communication device 600 includes components similar to those described in previous figures.

In this operating mode, two bypass signal paths are shown: a TX SAW-less path L14 and an RX SAW-less path L15. The TX SAW-less path L14 illustrates a bypass transmission sequence. A signal generated by a PA is routed to a TX Saw-less port of the integrated module, bypassing the internal SAW filter 11b. The signal is then routed back into the ASM 11a and is subsequently transmitted via the antenna A0. This path reduces signal loss during transmission.

The RX SAW-less path L15 illustrates a bypass reception sequence. A signal received by the antennas A1-A3 is routed through external switches (e.g., SW2) and the ASM 11a to a RX Saw-less port of the integrated module. Then, the signal is routed to an LNA (e.g., LNA 11e-4) through a trace and another RX Saw-less port of the integrated module. The signal is then directly amplified by the LNA (e.g., LNA 11e-4), bypassing the SAW filter 11b. This path enhances receiver sensitivity by avoiding the loss associated with the SAW filter 11b.

FIG. 11 thus illustrates a specific operating state where both the TX and RX signal paths are configured to bypass their respective filters to achieve optimal performance.

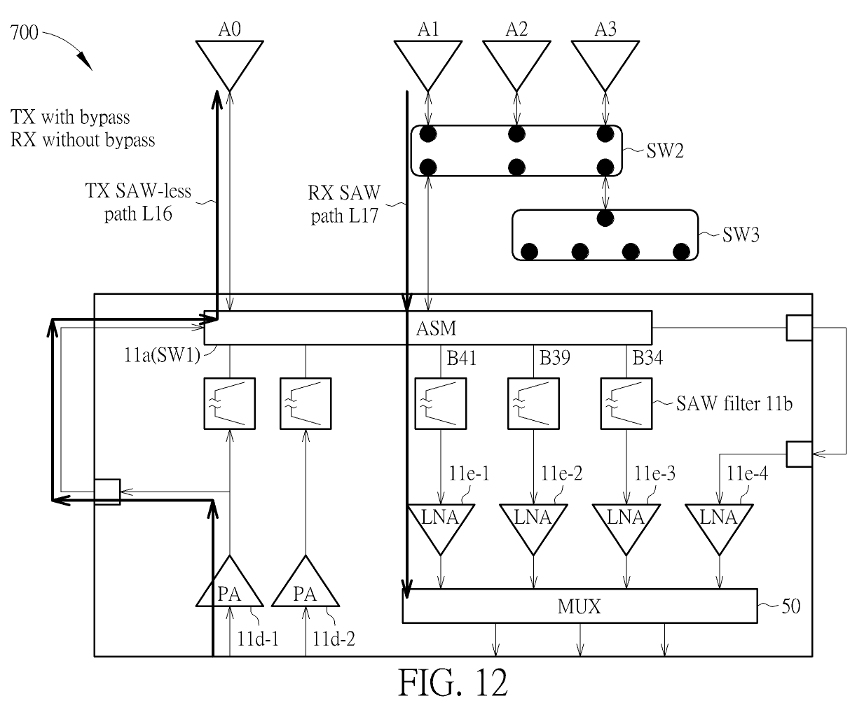

FIG. 12 is a schematic block diagram of a communication device 700 illustrating a mixed operating mode where the TX path operates with bypass and the RX path operates without bypass. This configuration demonstrates the flexibility of the device to independently configure the transmission and reception paths. The communication device 700 includes components similar to those described in previous figures.

In this mixed operating mode, two distinct signal paths are shown: a TX SAW-less path L16 and an RX SAW path L17. The TX SAW-less path L16 illustrates a bypass transmission sequence. A signal generated by a PA is routed to a TX Saw-less port, bypassing the internal SAW filter 11b. The signal is then routed back into the ASM 11a and is subsequently transmitted via the antenna A0. This path is selected to reduce signal loss during transmission, enhancing transmitter efficiency.

The RX SAW path L17 illustrates a standard reception sequence. A signal is received by the antenna A1 and is routed into the integrated module through the ASM 11a. The signal then passes through a corresponding SAW filter 11b before being amplified by an LNA. This path is selected when filtering of the received signal is required to reject interference.

FIG. 12 thus illustrates an adaptive operating state where the TX path is optimized for low loss, while the RX path is configured for robust interference rejection, demonstrating the independent control over the two signal chains.

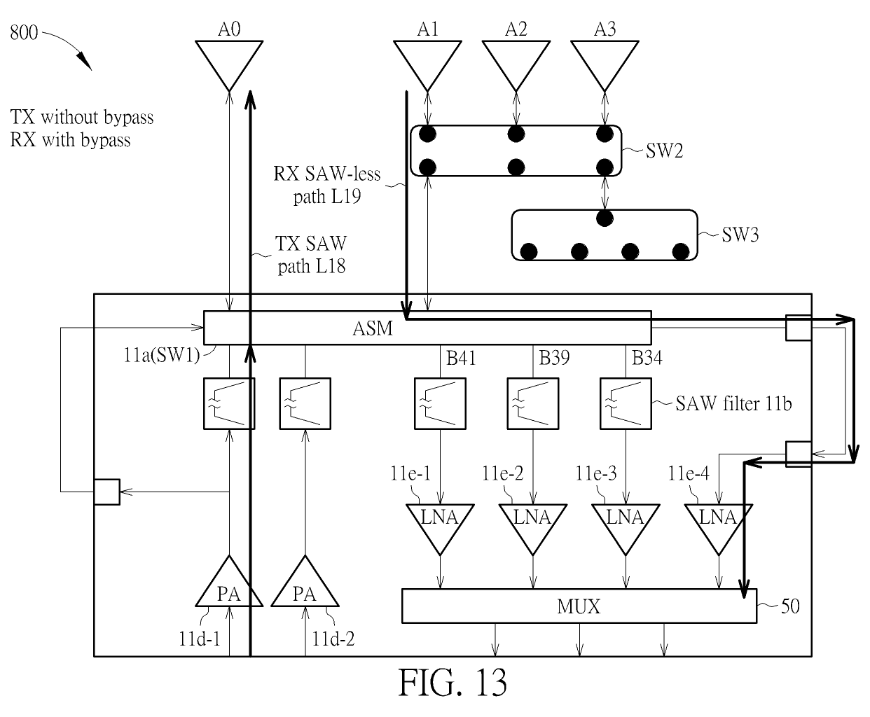

FIG. 13 is a schematic block diagram of a communication device 800 illustrating a mixed operating mode where the TX path operates without bypass and the RX path operates with bypass. This configuration represents a primary application of the present invention, where receiver sensitivity is enhanced while maintaining a standard transmission path. The communication device 800 includes components similar to those described in previous figures.

In this mixed operating mode, two distinct signal paths are shown: a TX SAW path L18 and an RX SAW-less path L19. The TX SAW path L18 illustrates a standard transmission sequence. A signal generated by a PA is routed through a corresponding SAW filter 11b and the ASM 11a, and is subsequently transmitted via the antenna A0. This path ensures that the transmitted signal is properly filtered.

The RX SAW-less path L19 illustrates a bypass reception sequence, which is a feature of the present invention. A signal received by the antennas A1-A3 is routed into the ASM 11a. The ASM 11a then directs the signal to a RX Saw-less port, from which the signal follows an external path to another port of the integrated module. The signal then re-enters the module and is directly amplified by an LNA (e.g., LNA 11e-4). This routing effectively bypasses the corresponding SAW filter 11b, thereby enhancing receiver sensitivity in low-interference environments.

FIG. 13 thus illustrates an operating state where the communication device prioritizes receiver performance by using a low-loss bypass path, while ensuring the integrity of the transmitted signal by using a conventional filtered path.

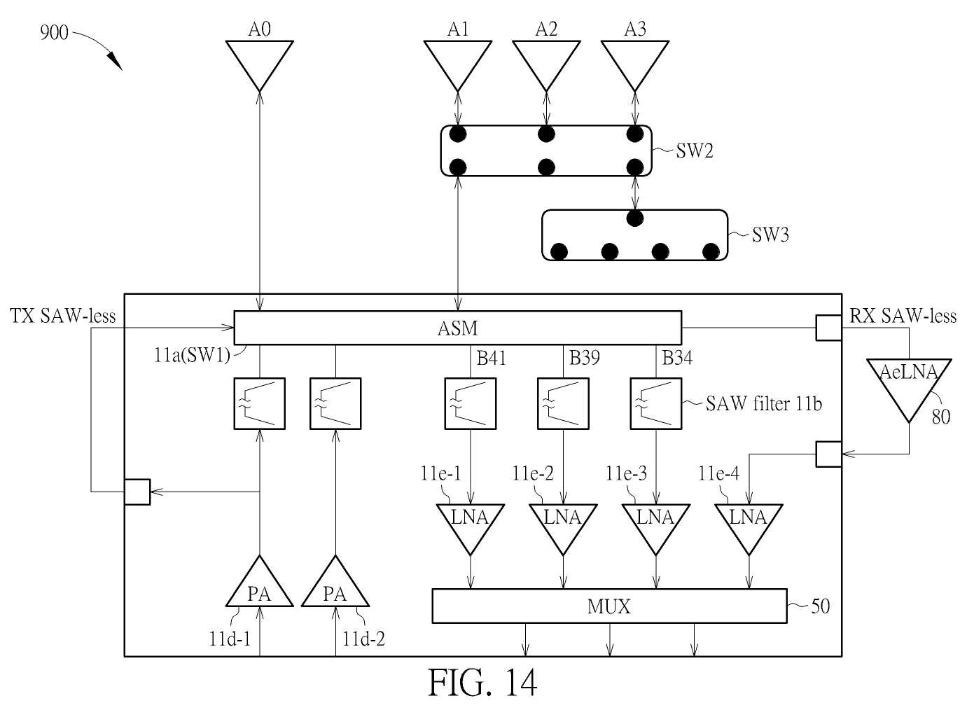

FIG. 14 is a schematic block diagram of a communication device 900 illustrating an enhanced embodiment of the external bypass path. The communication device 900 includes components similar to the aforementioned embodiments, with the addition of an enhanced component to further improve receiver performance.

In the architecture showed in FIG. 14, a portion of a second path (RX SAW-less path) is disposed externally to the integrated module. The feature of this embodiment is the inclusion of an additional external low noise amplifier (AeLNA) 80. The AeLNA 80 is disposed in the RX SAW-less path, coupled between the ASM 11a and the LNA 11e-4 of the integrated module.

In operation, when the SAW-less mode is selected, a received signal is routed through the ASM 11a and is then amplified by the AeLNA 80 before entering the integrated module. The signal, having been pre-amplified by the AeLNA 80, is then further amplified by an internal LNA (e.g., LNA 11e-4).

The purpose of the AeLNA 80 is to provide additional gain to the received signal in the bypass path. This additional gain can compensate for signal loss incurred in the external traces and components, and further boost the strength of weak signals. By amplifying the signal at an earlier stage, the AeLNA 80 can enhance the overall signal-to-noise ratio and receiver sensitivity of the communication device 900. This embodiment illustrates an optional enhancement to the bypass architecture, designed to maximize performance in challenging weak-signal environments.

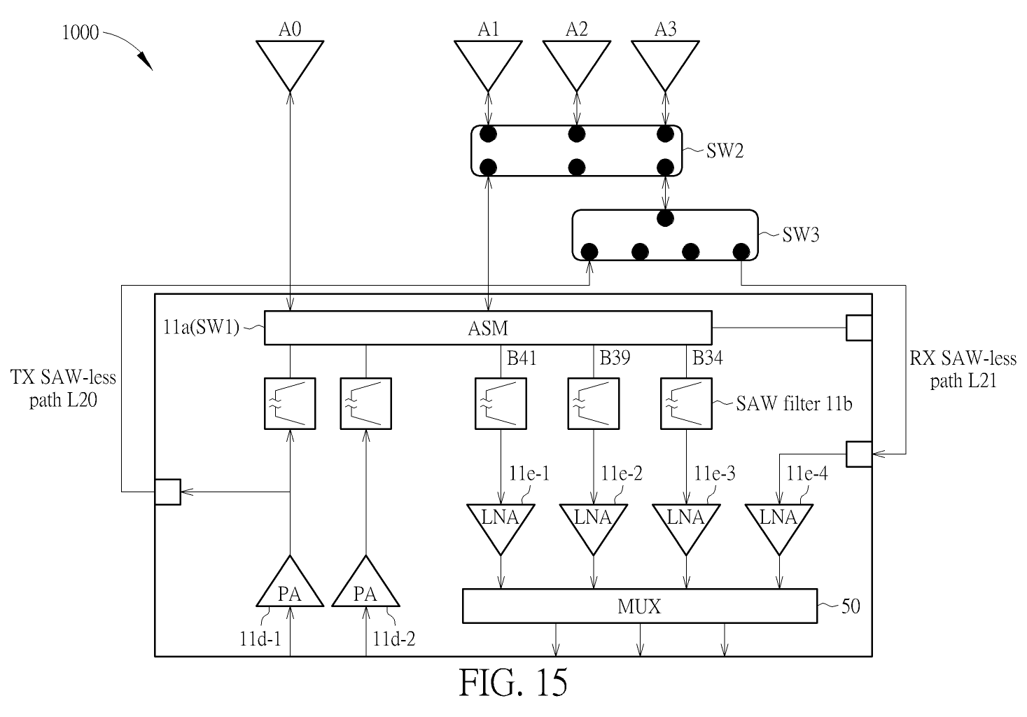

FIG. 15 is a schematic block diagram of a communication device 1000 illustrating a further optimized embodiment of the bypass path architecture. This configuration is designed to achieve a minimal signal loss by routing both the TX and RX bypass paths so that they do not pass through the ASM 11a. The communication device 1000 includes components similar to those described in previous figures.

In this embodiment, two optimized bypass paths are shown: a TX SAW-less path L20 and an RX SAW-less path L21. The TX SAW-less path L20 illustrates a bypass transmission sequence with minimal component traversal. A signal generated by a PA is routed to a TX Saw-less port of the integrated module. The signal then connects directly to an external switch (e.g., the third switch SW3) and is subsequently transmitted via an antenna (e.g., antennas A1~A3). In this configuration, the TX SAW-less path L20 completely bypasses both the internal SAW filter 11b and the ASM 11a, providing the lowest possible transmission loss.

The RX SAW-less path L21 illustrates a corresponding bypass reception sequence. A signal received by the antennas is routed through the external switches (e.g., the third switch SW3) and connects directly to a RX Saw-less port of the integrated module. The signal is then immediately amplified by an LNA (e.g., LNA 11e-4). The RX SAW-less path L21 completely bypasses both the ASM 11a and the SAW filter 11b.

FIG. 15 thus illustrates an embodiment focused on maximizing performance by creating the most direct signal paths possible, demonstrating the flexibility of the architecture to be adapted for different levels of performance optimization.

In summary, the present invention provides a communication device and method for adaptively selecting a receiver signal path. Unlike conventional designs with a fixed, lossy filter path, the embodiments introduce a dynamic selection between a first path comprising an SAW filter and a second, low-loss bypass path. The selection is controlled by a baseband IC based on a real-time assessment of the operating environment. An RFIC is configured to detect a plurality of parameters, such as a power level of a reference signal derived from a received signal, an interference power, and a quality of the received signal. Based on these parameters, the baseband IC determines the path to either reject interference or to improve receiver sensitivity. The architecture is flexible, supporting various embodiments including internal bypass paths, external bypass paths, and other optimization configurations. This adaptive approach of the embodiments overcomes the limitations of static front-end designs, providing improvements in receiver performance, particularly in weak signal conditions.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for adaptively selecting a signal path in a communication device, the communication device comprising a first path and a second path for receiving a signal, the first path comprising a surface acoustic wave (SAW) filter, the second path does not comprise a SAW filter, the method comprising:
detecting a power level of a reference signal derived from a received signal, wherein the received signal is received through one of the first path and the second path;
detecting an interference power of the received signal;
detecting a quality of the received signal;
selecting a path from the first path and the second path based on at least one of the power level of the reference signal, the interference power of the received signal, and the quality of the received signal; and
using the selected path to receive a subsequent signal.

2. The method of claim 1, wherein selecting a path from the first path and the second path comprises:
selecting the second path when the power level of the reference signal is less than a first threshold for a predetermined period.

3. The method of claim 1, wherein selecting a path from the first path and the second path comprises:
selecting the first path when the interference power of the received signal is greater than a second threshold.

4. The method of claim 1, wherein selecting a path from the first path and the second path comprises:
selecting the first path when the power level of the reference signal is greater than a third threshold and the quality of the received signal is less than a fourth threshold.

5. The method of claim 1, wherein selecting a path from the first path and the second path comprises:
selecting the second path when the power level of the reference signal is greater than a third threshold, and the quality of the received signal is greater than a fourth threshold.

6. The method of claim 1, wherein the detecting of the interference power of the received signal is performed during an initial symbol of a first slot of the signal, and the selected path is used to receive a second slot of the signal, wherein the second slot is subsequent to the first slot, and the detecting of the interference power of the received signal during the initial symbol comprises performing the detection a plurality of times.

7. The method of claim 1, wherein the communication device comprises a radio frequency integrated circuit (RFIC) and a baseband integrated circuit (IC), the method further comprising:
performing the detecting of the interference power of the received signal by the RFIC to generate a detected power value;
determining whether to select the first path or the second path by the baseband IC based on the detected power value; and
controlling a switch to select the first path or the second path by the RFIC based on a control signal generated by the baseband IC according to the determination.

8. The method of claim 1, wherein the first path comprises the SAW filter and a first LNA, and the second path does not comprise a SAW filter and comprises a second LNA, the communication device comprises an integrated module and a switch group external to the integrated module, wherein the first path is disposed within the integrated module, and wherein the second path comprises a trace disposed outside the integrated module and coupled between the switch group and the second LNA within the integrated module, and the second path is selected by the switch group.

9. The method of claim 1, wherein the communication device comprises an integrated module comprising a switch, wherein the first path and the second path are disposed within the integrated module, and wherein the switch selects the path from the first path and the second path.

10. A communication device, comprising:
an integrated module, comprising a first path and a second path, wherein the first path comprises a surface acoustic wave (SAW) filter and a first LNA coupled to the SAW filter, the second path comprises a second LNA and does not comprise a SAW filter;
a radio frequency integrated circuit (RFIC), coupled to the integrated module, the RFIC configured to:
detect an interference power of a received signal, wherein the received signal is received through one of the first path and the second path; and
a baseband integrated circuit (IC), coupled to the RFIC, the baseband IC configured to select a path from the first path and the second path based on at least one of a power level of a reference signal derived from the received signal, the interference power of the received signal, and a quality of the received signal, wherein the selected path is used to receive a subsequent signal.

11. The communication device of claim 10, wherein the baseband IC is further configured to select the second path when the power level of the reference signal is less than a first threshold for a predetermined period.

12. The communication device of claim 10, wherein the baseband IC is further configured to select the first path when the interference power of the received signal is greater than a second threshold.

13. The communication device of claim 10, wherein the baseband IC is further configured to select the first path when the power level of the reference signal is greater than a third threshold and the quality of the received signal is less than a fourth threshold.

14. The communication device of claim 10, wherein the baseband IC is further configured to select the second path when the power level of the reference signal is greater than a third threshold and the quality of the received signal is greater than a fourth threshold.

15. The communication device of claim 10, wherein the RFIC is configured to detect the interference power of the received signal during an initial symbol of a first slot of the signal, and wherein the baseband IC is configured to select one of the first path and the second path for a second slot of the signal, which the second slot is subsequent to the first slot, and the RFIC is configured to perform the detection of the interference power a plurality of times during the initial symbol.

16. The communication device of claim 10, wherein the baseband IC is configured to determine whether to select the first path or the second path and to generate a control signal according to the determination, and wherein the RFIC is further configured to control a switch to select a path from the first path and the second path based on the control signal.

17. The communication device of claim 16, wherein the switch comprises:
a switch group external to the integrated module;
wherein the first path is disposed within the integrated module, and wherein the second path comprises a trace coupled to the switch group and disposed outside the integrated module and the second LNA which is disposed within the integrated module and coupled to the trace through a first port of the integrated module, and the second path is selected by the switch group.

18. The communication device of claim 16, wherein the first path is disposed within the integrated module and the second path comprises a trace and the second LNA, wherein the trace is disposed outside the integrated module and coupled between a first port and a second port of the integrated module, and the second LNA is disposed within the integrated module and coupled to the trace through the first port of the integrated module, wherein the switch comprises a first switch coupled to the first path and the second port, for selecting the path from the first path and the second path, and the first switch is disposed within the integrated module.

19. The communication device of claim 16, wherein the first path is disposed within the integrated module and the second path comprises a third LNA and the second LNA, wherein the third LNA is disposed outside the integrated module and coupled between a first port and a second port of the integrated module, and the second LNA is disposed within the integrated module and coupled to third LNA through the first port of the integrated module, wherein the switch comprises a first switch coupled to the first path and the second port, for selecting the path from the first path and the second path, and the first switch is disposed within the integrated module.

20. The communication device of claim 11, wherein the first path and the second path are used to receive the signal at a first band, the integrated module further comprises another path comprising another SAW filter and another LNA, wherein the other path is used to receive another signal at another band, and the second path is used to receive the signal at the first band and the other signal at the other band at different times.
